(19) United States
(12) Patent Application Publication
(10) Pub. No.: US 2002/0016015 A1
(43) Pub. Date: Feb. 7, 2002

(54) Microelectronic-device fabrication method

(76) Inventor: Tomoharu Fujiwara, Tokyo (JP)

Correspondence Address: KLARQUIST SPARKMAN CAMPBELL, LEIGH & WHINSTON, LLP, One World Trade Center, Suite 1600, 121 S.W. Salmon Street, Portland, OR, 97204, US

(21) Appl. No.: 09/782,590

(22) Filed: Feb. 12, 2001

(30) Foreign Application Priority Data
Feb. 16, 2000 (JP) 2000-037364

(51) Int. Cl. G03F 9/00; H01L 21/00; H01L 21/302; H01L 21/461

(52) U.S. Cl. 438/50; 430/5; 438/736; 438/52

(57) ABSTRACT

Microelectronic-device fabrication methods are disclosed that include a microlithography step in which a pattern is defined on a mask divided into multiple subregions. The pattern includes pattern elements split among respective subregions that are exposed onto a resist layer of a wafer using a charged-particle-beam microlithography apparatus. In a first mask subregion, a first pattern-element portion is defined having a mating end that is complementary to a mating end of a second pattern-element portion defined in a second mask subregion. A mating end, rather than simply being blunt, typically has a protrusion and/or recess. If a first mating end has a protrusion, the protrusion is complementary to a corresponding protrusion on a second mating end, or to a recess on the second mating end. A mating end can have both at least one protrusion and at least one recess. Each protrusion tapers to a respective tip that can be rounded or sharp, and has a length of 1 to 5 times the width of the respective pattern-element portion. As transferred to the wafer, the stitched-together elements of the pattern exhibit less variation in line width at connected mating ends.

### TECHNICAL FIELD

The present invention relates in general to methods for fabricating semiconductor and other microelectronic devices. More specifically the invention relates to microlithographic methods as used in manufacturing microelectronic devices. The microlithographic methods are performed using a charged particle beam (e.g., electron beam) and a divided mask or reticle (termed “mask” herein) defining a pattern, wherein the mask is divided into multiple subregions defining respective portions of the pattern. Dividing the pattern involves splitting certain pattern elements into respective pattern-element portions located in different subregions, wherein exposure of the pattern involves re-joining (“stitching”) the pattern-element portions together as the images of the subregions are projected onto the surface of a wafer, thereby forming the complete pattern on the surface of the wafer.

### BACKGROUND

Usually, whenever a pattern for a microelectronic device is formed in a resist on the surface of a wafer using an electron-beam exposure (microlithography) apparatus, a stencil mask is employed. A stencil mask also is termed a “perforated mask” in which through-holes in a membrane define respective pattern elements. The through-holes transmit the electron beam in accordance with the respective shapes of the pattern elements. However, there are limits to the area that can be transferred at one time using a single mask. Furthermore, a “donut” pattern element cannot be defined in a single subregion of a stencil mask because the middle portion of the element is unsupported and falls out. Moreover, if a pattern element is very large, the stencil mask portion defining it tends to deform.

Accordingly, for certain pattern elements to be defined using a stencil mask, the pattern element as designed usually is split into portions defined in separate subregions of a mask. Exposure of the separate subregions is performed successively by irradiation using an electron beam or other charged particle beam. Successive exposure requires that the mask subregions be successively positioned for exposure using an electron-optical system. Thus, the pattern elements defined by the mask subregions are transferred to a resist layer on the surface of a wafer. The subregions defining the pattern-element portions are respectively transferred one at a time by deflecting the electron beam, or by moving the respective positions of the mask and wafer. As a result, the plurality of split pattern elements are exposed adjacent to each other to recreate the entire pattern, as designed, on the wafer.

FIGS. 15(a)-15(c) and 16(a)-16(c) show examples of split pattern elements. In cases where the pattern element is designed as a hollow “donut”-shaped element as shown in FIG. 15(a), the element as defined on the mask is split into the two portions shown in FIGS. 15(b) and 15(c) to prevent the center portion from dropping out. In cases where the pattern element as designed is a long linear element as shown in FIG. 16(a), the element as defined on the mask is split into the respective portions shown in FIGS. 16(b) and 16(c) to prevent deformation of the mask. The element portions are exposed adjacent each other on the wafer so that the entire pattern element as designed is transferred onto the wafer.

Whenever pattern elements are transferred in portions, as described above, there are limits to the accuracy with which the pattern-element portions split on the mask can be aligned on the surface of the wafer. Accordingly, whenever a plurality of split pattern elements are exposed while being positioned adjacent to each other or overlapped with one another, a considerable amount of positional deviation may occur. Pattern-element deformation caused by such positional deviation is a cause of faulty connections between pattern elements and of wiring interruptions, etc., and is a major problem in the manufacture of modern microelectronic devices having ultra-fine patterns.

A conventional method for preventing breaks in transferred pattern elements involves overlapping the interconnecting portions of the pattern elements, as shown in the shaded areas in FIG. 17. However, whenever portions of pattern elements are overlapped in this manner, the line width of the portions subjected to overlapping exposure is increased, as shown in FIG. 17. Furthermore, as a result of variation in the amount of overlapping caused by positional deviation errors of pattern elements as exposed onto the wafer, the degree of thickening of the line width also varies.

Japan Patent No. 2,706,099 discloses a procedure directed to this problem. Specifically, whenever adjacent portions of a pattern element are connected to each other, a first protruding part (that is smaller than the normal line width of the element in relative terms) is formed at the mating end of one of the portions. A second protruding part having a shape exhibiting linear symmetry with the first protruding part is formed at the mating end of the other portion. However, no approach for optimizing the shapes of the mating ends has been established in cases where the respective shapes of mating ends of pattern elements are finely worked.

In particular, in cases where protruding parts are formed in the mating ends of respective pattern-element portions, and the pattern-element portions are joined together by overlapping the protruding parts of these ends, the widening of the line width in regions of the mating ends subjected to multiple exposure depends greatly on the degree of blur of the exposing beam. Since beam blur of an electron-beam lithographic exposure apparatus varies with changes in the space-charge effect and other phenomena, the dimensions of the protruding parts formed in the mating ends of pattern elements cannot be made the same at all locations on the mask. Also, the line width varies in areas occupied by mating ends whenever the degree of beam blur varies due to instability of the electron-optical system.

### SUMMARY

In light of the above, an object of the invention is to provide microelectronic-device fabrication methods exhibiting reduced variation, in the line width of interconnected mated ends of elements of a pattern, that otherwise occurs whenever the pattern is defined by multiple split-pattern portions on respective portions of a mask, and an electron-beam lithographic exposure apparatus is used to transfer the split pattern elements onto a resist applied as a coating to a wafer, thereby more reliably connecting the multiple split pattern elements together as imaged on the wafer.

Certain methods according to the invention are directed to respective lithographic processes set forth in the context of a method for manufacturing a microelectronic device. The lithographic processes achieve transfer of a pattern to a resist layer on a wafer. The pattern includes pattern elements split among respective mask subregions that are exposed onto the resist using a charged-particle-beam lithographic-exposure apparatus that places and stitches together images of the mask subregions on the wafer to form the pattern on the wafer.

According to a first embodiment, in a first mask subregion, a first pattern-element portion is defined having a line width and a respective mating end including a protrusion in which the line width progressively narrows toward a tip of the protrusion. The protrusion has a length that is 1 to 5 times the line width of the first pattern-element portion. In a second mask subregion, a second pattern-element portion is defined having a line width and a respective mating end including a recess shaped complementarily to the protrusion. The recess has a length that is 1 to 5 times the line width of the second pattern-element portion. Consequently, when the first and second pattern-element portions are exposed onto the resist, the portions collectively form a contiguous pattern element. Using a charged-particle-beam lithographic-exposure apparatus, the first and second mask subregions are transferred onto the resist in a manner such that the respective mating ends of the first and second pattern-element portions are stitched together in the pattern on the wafer.

According to a second embodiment, in a first mask subregion, a first pattern-element portion is defined having a line width and a first mating end shaped as a recess flanked by respective protrusions. The protrusions each have a respective rounded tip and a respective width that progressively narrows toward the respective rounded tip. In a second mask subregion, a second pattern-element portion is defined having a line width and a second mating end that is substantially complementary to the first mating end. The second mating end includes a step region disposed so as to be located, whenever respective images of the first and second pattern-element portions are stitched together, adjacent the respective rounded tips of the protrusions of the first mating end. The second mating end also includes a protrusion extending from the step region and disposed so as to be located, whenever respective images of the first and second pattern-element portions are stitched together, in the recess of the first mating end. Using the charged-particle-beam lithographic-exposure apparatus, the first and second mask subregions are transferred onto the resist in a manner such that the first and second mating ends are stitched together in the pattern on the wafer. The recess in the first mating end can be defined with a length that is 1 to 5 times the line width of the first pattern-element portion. Similarly, the protrusion of the second mating end can be defined with a length of 1 to 5 times the line width of the second pattern-element portion.

According to a third embodiment, in a first mask subregion, a first pattern-element portion is defined having a line width and a respective mating end defining a respective protrusion extending at an oblique angle relative to a longitudinal direction of the first pattern-element portion. The protrusion progressively narrows toward a distal tip of the protrusion. In a second mask subregion, a second pattern-element portion is defined having a line width and a respective mating end defining a respective protrusion extending at an oblique angle relative to a longitudinal direction of the second pattern-element portion. The protrusion has a profile that is complementary to the protrusion of the mating end of the first pattern-element portion. Using the charged-particle-beam lithographic-exposure apparatus, the first and second mask subregions are transferred onto the resist in a manner such that the respective mating ends of the first and second pattern-element portions are stitched together in the pattern on the wafer. The protrusion of the mating end of the first pattern-element portion can be defined such that the distal tip of the protrusion is rounded. In such an instance, the protrusion of the first pattern-element portion desirably includes a proximal step region situated so as to be adjacent the rounded distal tip of the protrusion of the mating end of the second pattern-element portion whenever the first and second pattern-element portions are stitched together on the wafer. Similarly, the protrusion of the mating end of the second pattern-element portion can be defined such that the distal tip of the protrusion is rounded. In such an instance, the protrusion of the second pattern-element portion desirably includes a proximal step region situated so as to be adjacent the rounded distal tip of the protrusion of the mating end of the first pattern-element portion whenever the first and second pattern-element portions are stitched together on the wafer. The protrusion of the first pattern-element portion desirably is defined with a length of 1 to 5 times the line width of the first pattern-element portion. Similarly, the protrusion of the second pattern-element portion desirably is defined with a length of 1 to 5 times the line width of the second pattern-element portion.

According to a fourth embodiment, in a first mask subregion, a first pattern-element portion is defined having a line width and a respective mating end including a respective protrusion having an edge extending obliquely to a length dimension of the first pattern-element portion. The protrusion includes a respective recess. In a second mask subregion, a second pattern-element portion is defined having a line width and a respective mating end that is complementary to the mating end of the first pattern-element portion. Using the charged-particle-beam lithographic-exposure apparatus, the first and second mask subregions are transferred onto the resist in a manner such that the respective mating ends of the first and second pattern-element portions are stitched together in the pattern on the wafer.

The recess defined in the protrusion of the mating end of the first pattern-element portion can be configured to divide the respective protrusion into first and second protrusion portions that flank the recess, wherein each protrusion portion has a respective rounded distal end. The mating end of the second pattern-element portion can be defined to include a respective protrusion having an edge extending obliquely to a length dimension of the second pattern-element portion. The protrusion desirably includes a recess that divides the respective protrusion into first and second protrusion portions that flank the recess, wherein each protrusion portion having a respective rounded distal end. In the mating end of the first pattern-element portion, the obliquely extending edge desirably includes a respective step region situated so as to be located adjacent a rounded tip of a protrusion portion of the mating end of the second pattern-element portion when the first and second pattern-element portions are stitched together on the wafer. Similarly, in the mating end of the second pattern-element portion, the obliquely extending edge desirably includes a respective step region situated so as to be located adjacent a rounded tip of a protrusion portion of the mating end of the first pattern-element portion when the first and second pattern-element portions are stitched together on the wafer. The recess defined in the protrusion of the mating end of the first pattern-element portion desirably is defined to have a length of 1 to 5 times the line width of the first pattern-element portion.

In the methods described above, portions of pattern elements (i.e., regions of pattern elements where respective pattern-element portions are joined together as projected on the wafer) can be subjected to double exposure due to positional errors. However, undesirable consequences of such double exposures, such as line-width thickening or line-width narrowing, or breaks in pattern elements, are reduced by configuring the mating ends of pattern-element portions (according to certain aspects of the invention) so as to fit together in a complementary manner when projected onto the wafer. Even under conditions of variable beam blur of the lithographic apparatus, line-width variation is reduced, yielding more accurate pattern transfer.

### BRIEF DESCRIPTION OF THE DRAWINGS

FIGS. 1(a)-1(c) are respective plan views illustrating the splitting of a pattern element as used in a microelectronic-device fabrication method according to a first representative embodiment.

FIG. 2 is an optical diagram illustrating image-focusing relationships in the electron-optical system of an electron-beam lithographic exposure apparatus.

FIGS. 3(a)-3(f) are respective plan views illustrating respective variations in the line width of a pattern element as transferred to the resist. The variations occur due to respective amounts of overlapping of the pattern-element portions as projected from two respective mask subregions. The pattern-element portions are configured as shown in FIG. 16(a).

FIGS. 4(a)-4(i) are respective plan views illustrating respective variations in the line width of a pattern element as transferred to the resist. The variations occur due to respective amounts of overlapping of the pattern-element portions as projected from two respective mask subregions. The pattern-element portions have protruding parts on their respective mating ends.

FIGS. 5(a)-5(f) are respective plan views illustrating respective variations in the line width of a pattern element as transferred to the resist. The variations occur due to respective amounts of overlapping of the pattern-element portions as projected from two respective mask subregions. The pattern-element portions are configured as shown in FIGS. 1(a)-1(c).

FIGS. 6(a)-6(b) are respective plan views illustrating respective pattern-element portions having mating end that are rounded due to a fabrication error of the mask-drawing apparatus.

FIGS. 7(a)-7(b) are respective plan views illustrating the splitting of a pattern element as used in a microelectronic-device fabrication method according to a second representative embodiment.

FIG. 8 is a flow chart illustrating an exemplary simulation used for optimizing the design shape parameters for pattern elements in the second representative embodiment.

FIGS. 9(a)-9(c) are respective plan views illustrating the splitting of a pattern element as used in a microelectronic-device fabrication method according to a third representative embodiment.

FIGS. 10(a)-10(f) are respective plan views illustrating respective variations in the line width of a pattern element as transferred to the resist. The variations occur due to respective amounts of overlapping of the pattern-element portions as projected from two respective mask subregions. The pattern-element portions are configured as shown in FIGS. 9(a)-9(c).

FIGS. 11(a)-11(b) are respective plan views illustrating the splitting of a pattern element as used in a modification of the third representative embodiment.

FIGS. 12(a)-12(c) are respective plan views illustrating the splitting of a pattern element as used in a microelectronic-device fabrication method according to a fourth representative embodiment.

FIGS. 13(a)-13(f) are respective plan views illustrating respective variations in the line width of a pattern element as transferred to the resist. The variations occur due to respective amounts of overlapping of the pattern-element portions as projected from two respective mask subregions. The pattern-element portions are configured as shown in FIGS. 12(a)-12(c).

FIGS. 14(a)-14(b) are respective plan views illustrating the splitting of a pattern element as used in a modification of the fourth representative embodiment.

FIG. 15(a) is a plan view of a hollow (“donut”) pattern element, and FIGS. 15(b)-15(c) are respective plan views of respective pattern-element portions obtained by splitting the donut pattern element.

FIG. 16(a) is a plan view of a long linear pattern element, and FIGS. 16(b) 16(c) are respective plan views of respective pattern-element portions obtained by splitting the linear pattern element.

FIG. 17 is a plan view illustrating the thickening of the line width of conjoined pattern-element portions in a double-exposed region portion resulting from the overlapping of the respective mating ends of the pattern-element portions.

### DETAILED DESCRIPTION

Representative embodiments are described below with reference to the attached figures.

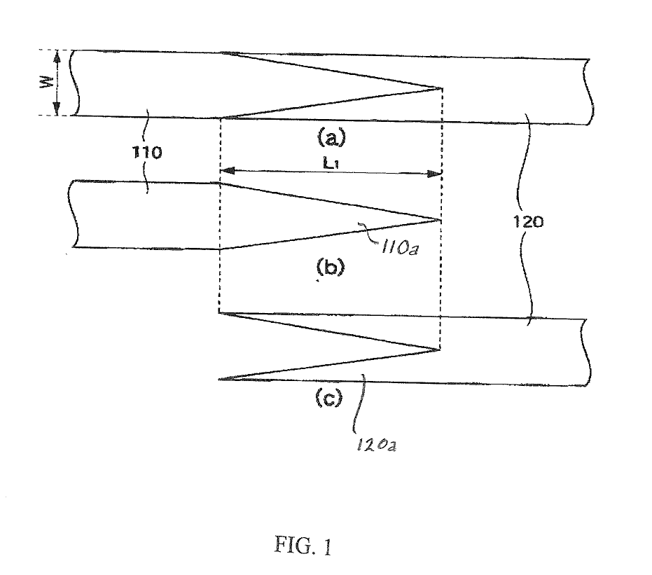

A first representative embodiment is shown in FIGS. 1(a)-1(c), showing splitting of a long linear pattern element (FIG. 1(a)) into two complementary pattern-element portions 110, 120 (FIGS. 1(b) and 1(c), respectively). The pattern-element portions 110, 120 are defined in respective subregions of the mask (or in respective subregions of separate masks). The portion 110 has a protruding mating end 110a, and the portion 120 has a recessed mating end 120a shaped to be complementary to the mating end 110a. The dimensions of these features will be described in detail later. The respective mask subregion defining the pattern-element portion 110 and the respective mask subregion defining the pattern-element portion are successively irradiated with an electron beam (or other charged particle beam) to transfer the respective pattern-element portions onto a resist layer formed on the surface of a wafer. The pattern-element portions 110, 120 can delimit a region such as a gate electrode, impurity-diffusion region, wiring, etc., of a microelectronic device formed on the wafer.

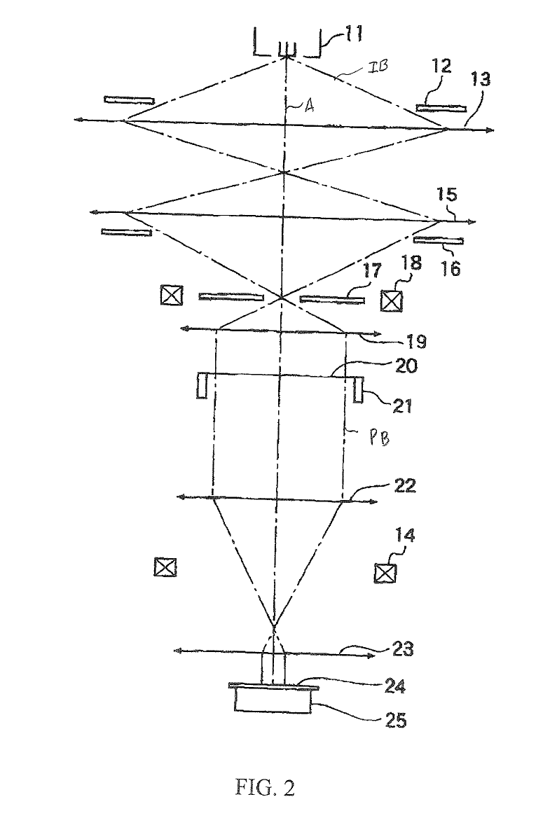

A representative electron-beam exposure apparatus used to perform this exposure is described with reference to FIG. 2. An electron gun 11 emits an electron beam IB in a downstream direction along an axis A. Two condenser lenses 13 and 15 are situated downstream of the electron gun 11. The electron beam IB passes through the condenser lenses 13, 15, and forms a crossover on the axis A in an aperture defined by a blanking diaphragm 17. The current density with which the mask 20 is irradiated can be varied by operating the two condenser lenses 13, 15 in concert as a zoom lens.

Two diaphragms 12, 16 defining respective rectangular apertures (subfield-limiting apertures) are disposed above and below the condenser lenses 13, 15, respectively. These rectangular apertures transmit only a portion of the electron beam IB sufficient to illuminate one subregion (also termed a “subfield”) of the mask 20 contained in a main optical field of the electron-optical system. The image formed by the aperture of the first diaphragm 12 is focused on the second diaphragm 16 by the condenser lenses 13, 15.

A subfield-selection deflector 18 is disposed adjacent the blanking diaphragm 17. The subfield-selection deflector 18 successively scans the electron beam 18 mainly in the X direction, and exposes a plurality of subfields arrayed in the X direction within the main optical field. A condenser lens 19 is disposed beneath the subfield-selection deflector 18. The condenser lens 19 collimates the electron beam IB and directs the collimated beam onto the mask 20, thereby forming an image of the aperture of the second diaphragm 16 on the mask 20.

The electron-optical system, described above, located between the electron gun 11 and the mask 20 is the “illumination-optical system” used to direct the electron beam IB (“illumination beam”) onto the mask 20. Downstream of the mask 20 is a “projection-optical system” used to direct a “patterned beam” PB (formed by passage of electrons of the illumination beam IB through the mask 20) from the mask 20 to a wafer 24. The projection-optical system includes two projection lenses (objective lenses) 22, 23 and an image-positioning deflector 14 disposed between the projection lenses 22, 23.

In the electron-beam exposure apparatus of FIG. 2, the subfield-selection deflector 18 deflects the electron beam IB as required to cause the electron beam IB to strike the mask subregions in a sequential manner at high speed. Meanwhile, the image-positioning deflector 14 deflects the patterned beam PB as required to position the projected images of the subregions adjacent each other in coordination with appropriate movement of a wafer stage 25 on which the wafer 24 is mounted for exposure.

To eliminate having to provide a large deflection range of the illumination beam IB, the mask 20 is mounted to a mask stage 21 that is movable in the X direction and Y direction. As noted above, the wafer 24 is mounted on a wafer stage 25 that can move in the X direction and the Y direction. On the mask 20, the subregions (subfields) are arrayed in parallel rows (each extending in the X direction). Multiple rows are arrayed in the Y direction in groups called “stripes.” Multiple stripes form the mask pattern: The constituent rows in each stripe are successively placed for exposure by moving the mask stage 21 and wafer stage 25 in opposite Y directions. The stripes are successively exposed by intermittently moving the mask stage 21 and wafer stage 25 in the X direction. Moreover, the mask stage 21 and wafer stage 25 are each equipped with accurate position-measurement systems employing laser interferometers. The respective rows and subfields are accurately joined together on the wafer 24 as required by appropriate adjustments of beam position using a separate alignment means or deflector.

Whenever a subfield of the mask 20 is being illuminated by the illumination beam IB, the resulting patterned beam PB is reduced (demagnified) by the projection lenses 22, 23 and deflected as required to focus an image of the subfield at a specified location on the wafer 24. The surface of the wafer 24, on which an appropriate conductive film or insulating film has been formed, is coated with a suitable resist. In areas of the resist subjected to a patterned-beam dose exceeding a specified threshold, the resist can be made more durable than unexposed resist and caused to remain (in the case of a negative resist) on the wafer after resist development. Thus, the pattern defined by the mask 20 is transferred to the resist on the wafer 24.

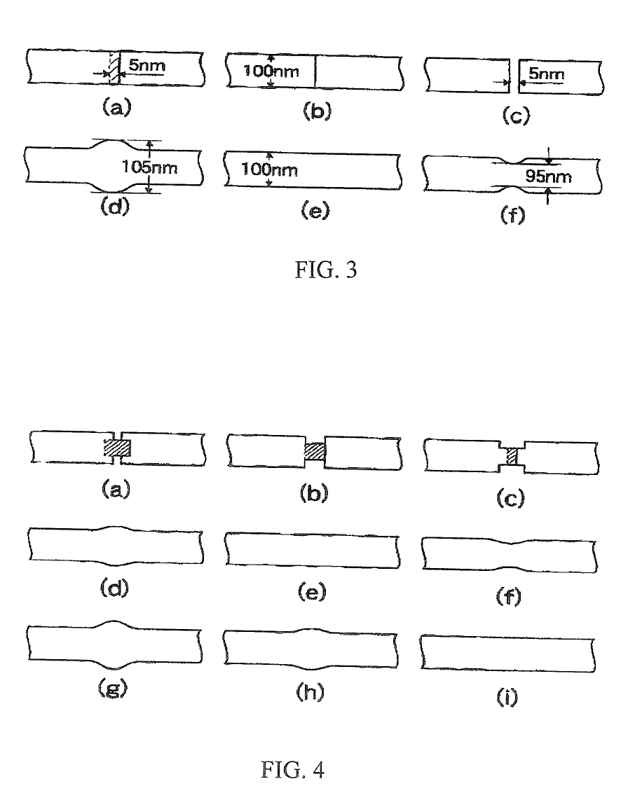

The line width of a pattern element transferred to the resist varies mainly as a result of positional deviations of the pattern element on the wafer attributable to a positional error E₁ caused by the deflectors of the projection-optical system and to a positional error E₂ of the mask stage 21 and wafer stage 25. FIGS. 3(a)-3(f) show exemplary variations in the line width of a linear pattern element transferred to the resist, as affected by the amount of overlapping of respective pattern-element portions projected from two respective subregions of the mask 20. Here, the design-specified line width of the linear pattern element is 0.1 μm (100 nm).

If the amount of overlapping of the projected pattern-element portions is zero as shown in FIG. 3(b), then the line width of the transferred pattern element is unchanged at 100 nm as shown in FIG. 3(e). If the projected pattern-element portions overlap by 5 nm as shown in FIG. 3(a), then the line width of the transferred pattern element in the connected region is increased (“thickened”) to 105 nm as shown in FIG. 3(d). Conversely, if the projected pattern-element portions are “underlapped” by 5 nm as shown in FIG. 3(c), then the line width of the transferred pattern element in the connected region is decreased (narrowed) to 95 nm as shown in FIG. 3(f). Accordingly, whenever it is desired to control the amount of line-width variation in the connected region of a transferred pattern element to ±5% or less, the positional errors E₁ and E₂ for the respective projected pattern elements as achieved by the electron-beam exposure apparatus should not exceed ±(5/√2)=±3.5 nm. This represents an extremely strict accuracy requirement for pattern-element positioning.

FIGS. 4(a)-4(i) show variations in the line width of a transferred linear pattern element as a function of the amount of overlapping of constituent pattern-element portions as projected from two respective subregions of the mask, in a case in which the pattern-element portions have protrusions on their respective mating ends. By optimizing the dimensions of the protrusions in accordance with the amount of beam blur exhibited by the electron beam produced by the electron-beam exposure apparatus, it is possible to obtain an unchanged line width on the transferred pattern element, as shown in FIG. 4(e). For example, this line width is design-specified at 100 nm, and is achieved where the amount of overlapping of the projected pattern-element portions is a standard design-specified amount, as shown in FIG. 4(b). If the projected pattern-element portions overlap more than the standard design-specified amount (FIG. 4(a)), then the resulting increase in the line width of the transferred pattern element (FIG. 4(d)) is comparatively small (compare FIG. 4(d) with FIG. 3(d)). Under such conditions, even if a positional error of approximately +13 nm occurs in the projected pattern-element portions, the increase in the line width of the transferred pattern element can be kept to approximately +5%. Conversely, if the projected pattern-element portions are overlapped less (FIG. 4(c)) than the standard design-specified amount, then the connecting region is still subjected to double exposure, as shown in FIG. 4(f). As a result, so that there is very little risk of the transferred pattern element being broken or interrupted.

In an electron-beam exposure apparatus, beam blur varies with changes in pattern-element density of the pattern, beam-deflection position, and other parameters. Whenever a large amount of beam blur is present, transferred pattern elements formed by conjoining respective pattern-element portions are thickened in the respective connecting regions, as shown in FIG. 4(h), even if the amount of overlap is the standard design-specified amount (FIG. 4(b)). Whenever the projected pattern-element portions are overlapped more than the standard design-specified amount, (FIG. 4(a)), the line width of the connection region of the transferred pattern element is thickened even more, as shown in FIG. 4(g). In such cases, it is necessary to cause the projected pattern-element portions to overlap less than the standard design-specified amount, as shown in FIG. 4(c), so as to produce the desired transfer-pattern element, as shown in FIG. 4(i).

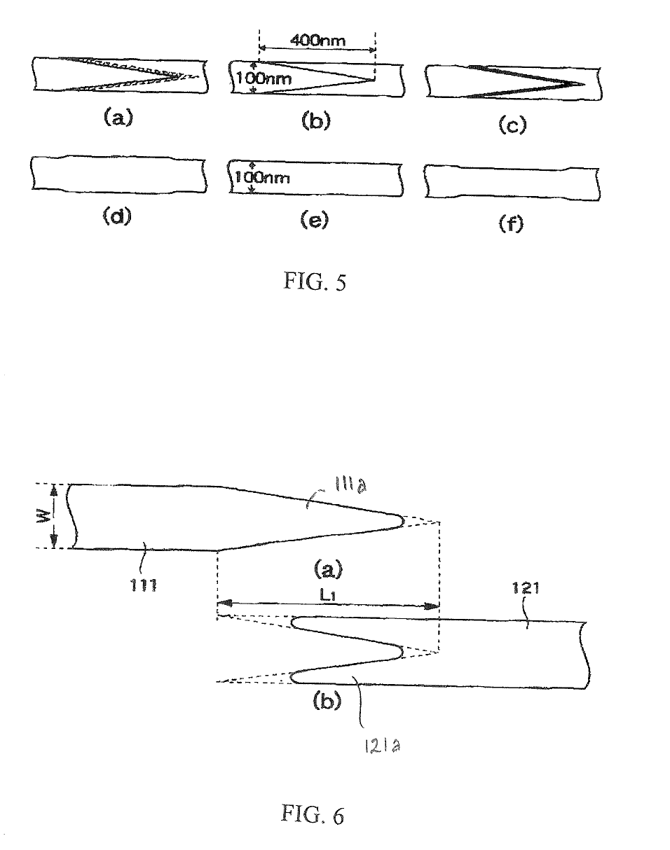

FIGS. 5(a)-5(f) show variations in the line width of a transferred linear pattern element as a function of the amount of overlapping of constituent pattern-element portions as projected from respective subregions of the mask, in a case in which the pattern-element portions are as shown in FIGS. 1(a)-1(c). Here, the design-specified line width W of the pattern element in FIG. 1(a) is 0.1 nm (100 μm), and the length L₁ of the protrusion 110a (FIG. 1(b)) and of the complementary mating end 120a (FIG. 1(c)) is 400 nm.

Whenever the overlap of the projected pattern-element portions is just zero as shown in FIG. 5(b), the line width of the transferred pattern element is unchanged at the desired 100 nm, as shown in FIG. 5(e). Whenever the projected pattern-element portions overlap (due to an error in pattern-element positioning on the wafer), as shown in FIG. 5(a), a slight thickening of the line width of the transferred pattern element is evident. The thickened line width is dispersed in the longitudinal direction of the pattern element. Consequently, the variation in the line width of the transferred pattern element is relatively small, as shown in FIG. 5(d). Conversely, if the projected pattern-element portions actually have an intervening space between the respective mating ends (a condition termed “underlap” due for example to an error in pattern-element positioning on the wafer), as shown in FIG. 5(c), a slight narrowing of the line width of the transferred pattern element is evident. The narrowed line width is dispersed in the longitudinal direction of the pattern element. Consequently, the variation in the line width of the transferred pattern element is relatively small, as shown in FIG. 5(f). Based on these results, the variation in line width of the transferred pattern is ±5% or less, even if the positional error of the projected pattern elements is approximately ±20 nm.

Referring further to the case of zero overlap as shown in FIG. 5(b), continuity of desired line width of the transferred pattern element is obtained regardless of beam blur. Even if adjoining pattern-element portions overlap or underlap, the variation in the line width of the transferred pattern element caused by variation in beam blur is dispersed longitudinally over the pattern element. This provides a pattern-element line width that is extremely stable to positional errors of the pattern and to beam blur.

In view of the foregoing, a large value of the length L₁ (FIG. 1(a)) is desirable. However, as L₁ increases, the apex of the protrusion 110a (and the deepest portion of the complementary portion 120a) have increasingly sharper angles. These trends increase the difficulty of mask fabrication. Using current fabrication techniques the length L₁can be increased to approximately 500 nm. In general, it is appropriate to establish the length L₁ at 1 to 5 times the design-specified line width W of the pattern element.

A second representative embodiment of a microelectronic-device fabrication method is directed to situations in which the acute angles of mating ends of pattern-element portions are blunted or rounded. Mating ends having these configurations can arise as a result of mask-fabrication errors and/or problems in mask drawing. Exemplary rounded mating ends 111a, 121a are shown in FIGS. 6(a)-6(b), respectively. In an attempt to interconnect (“stitch together”) the mating ends having such configurations, obtaining the required interconnection accuracy is very difficult to impossible.

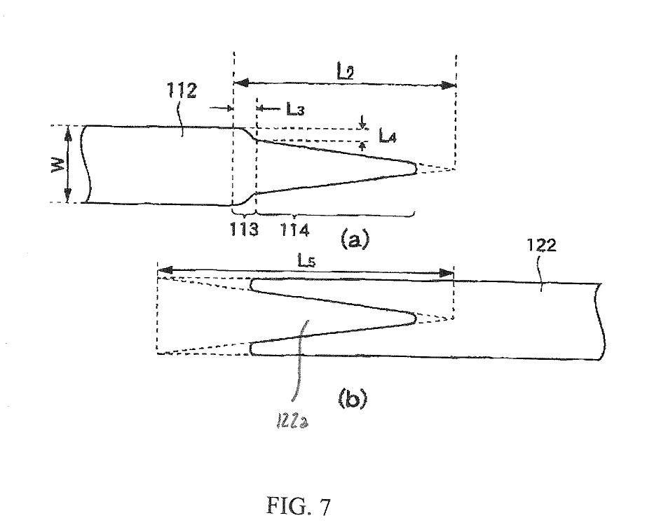

Under such conditions, and also taking into account errors that occur during mask fabrication, optimization of the interconnection of pattern-element portions is performed, according to this embodiment, in a manner as shown in FIGS. 7(a)-7(b). Specifically, the pattern-element portion 112 shown in FIG. 7(a) includes step regions 113 having dimensions L₃ and L₄ as shown. The pattern-element portion 112 also includes a protrusion 114 that is contiguous with the step regions 113. These features improve the stitching of the pattern-element portion 112 (FIG. 7(a)) with the pattern-element portion 122 (FIG. 7(b)). The total length of the step regions 113 plus the protrusion 114 (including the portions indicated by dashed line in FIG. 7(a) is designated as L₂. Since the complementary recession 122a in the mating end of the pattern-element portion 122 also is shortened due to blunting, the length L₁ shown in FIG. 1(a) is corrected in FIG. 7(b) to the length L₅ during the design of the pattern-element portion 122. The shape of the pattern-element portion 112 in FIG. 7(a) is designed on the basis of the corrected length L₅. Note that rounded acute angles occur at three places in the pattern-element portion 122.

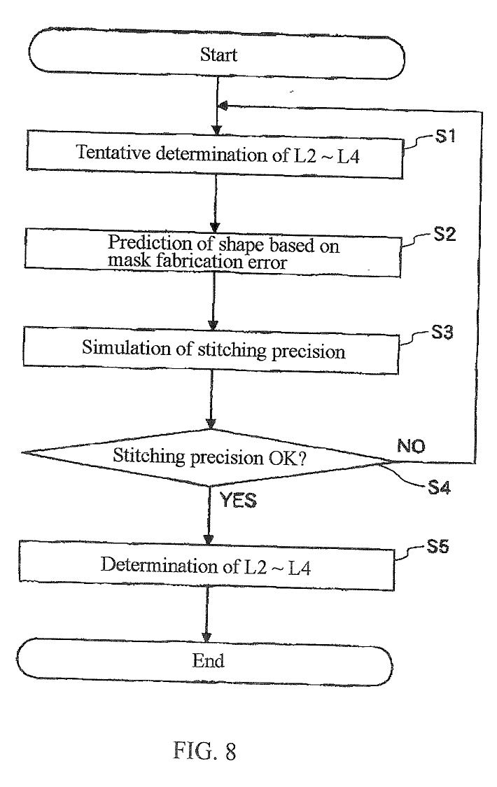

The design-specified parameters L₂, L₃, L₄, etc., of the pattern-element portion 112 can be optimized by a simulation protocol as outlined in FIG. 8. First, in step S1, the shape of a pattern-element portion is “tentatively” determined without considering mask-fabrication errors. In this step, the parameters L₂-L₄ are predicted beforehand. Next, in step S2, mask-fabrication errors are applied to the tentatively determined shape of the pattern-element portion. Also, the shape of the pattern-element portion in the mask being fabricated is predicted. The mask-fabrication errors include the beam blur occurring in the mask-drawing apparatus, minimum address size, and other factors. For example, by approximating beam blur of the mask-drawing apparatus using a Gaussian distribution, it is possible to calculate the shape of a pattern-element portion in the mask from a convolution of the design-specified pattern and the Gaussian distribution.

Next, in step S3, the stitching accuracy of pattern-element portions is determined by simulation. In this simulation, a first calculation involves a convolution of the pattern-element portion predicted in step S2 and beam blur of the electron-beam exposure apparatus. This calculation is respectively performed for the pattern-element portion 112 (FIG. 7(a)) and the pattern-element portion 122 (FIG. 7(b)). Subsequently, it is assumed that the pattern-element portion 112 and the pattern-element portion 122 are disposed in specified respective locations for stitching together. Stitching accuracy is determined by calculating the line width of the pattern element formed on the wafer, based on the electron-beam dose applied to the resist on the wafer.

In step S4, stitching accuracy is determined on the basis of the results obtained in step S3. In cases where stitching accuracy does not satisfy a specified standard, the process returns to step S1, and calculations are repeated with appropriate changes to the the parameters L₂-L₄. Thus, a pattern-element portion having an optimal shape, taking into consideration the fabrication error of the mask-drawing apparatus, can be determined from the parameters L₂-L₄.

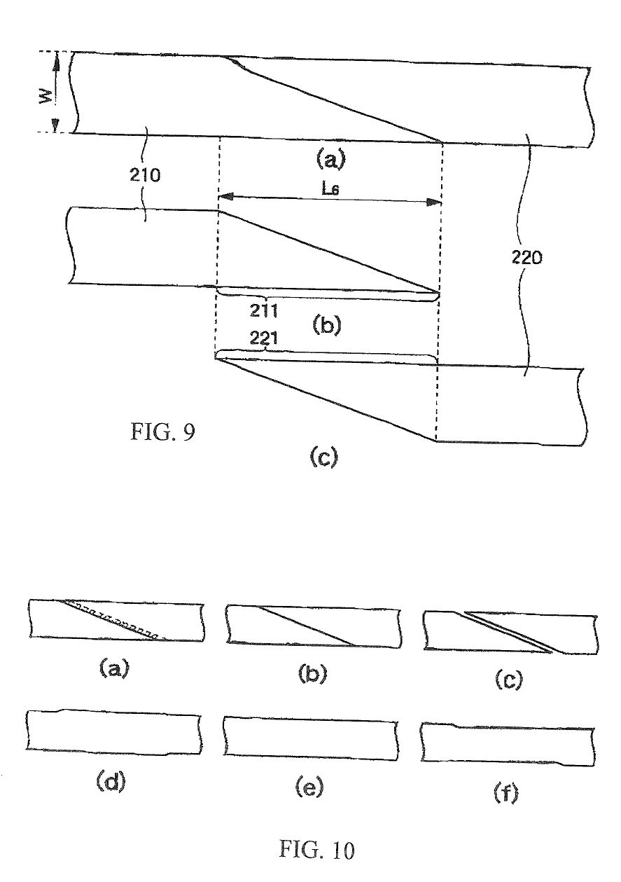

A microelectronic-device fabrication process according to a third representative embodiment now is described with reference to FIGS. 9(a)-9(c). FIG. 9(a) depicts a long linear pattern element that is split into respective pattern-element portions 210, 220 shown in FIGS. 9(b)-9(c), respectively. The pattern-element portions 210, 220 are defined in respective subregions of a mask (or on separate masks). The pattern-element portion 210 has a mating end 211 that is cut at an oblique angle with respect to the length of the pattern-element portion. The pattern-element portion 220 has a similar but complementary mating end 221. The pattern-element portions 210, 220 are connected (stitched) together at such mating ends when the respective mask subregions are projected onto the wafer. Variations in line width of the resulting pattern element are substantially reduced in the same manner as in the first representative embodiment, even if the amount of overlap of the two pattern-element portions varies.

FIGS. 10(a)-10(f) show variations in line width of the pattern element formed from stitching together of the pattern-element portions 210, 220 as transferred to the resist, as a function of the amount of overlap of the respective mating ends. Here, the design-specified line width W of the pattern element shown in FIG. 9(a) is, for example, 0.1 μm (100 nm), and the length L₆ of the oblique mating ends 211, 221 is 400 nm.

Whenever the amount of overlap of the projected pattern-element portions is zero as shown in FIG. 10(b), the line width of the resulting pattern element, as transferred to the wafer is unchanged at the desired 100 nm as shown in FIG. 10(e). Whenever the respective mating ends of the projected pattern-element portions overlap, as shown in FIG. 10(a), due to a positioning error, the line width of the resulting pattern element as transferred to the wafer exhibits some thickening as shown in FIG. 10(d). The thickening is dispersed in the longitudinal direction of the pattern element, yielding a relatively small variation in the line width. Conversely, whenever the projected pattern-element portions “underlap,” as shown in FIG. 10(c), due to a positioning error, the line width of the resulting pattern element as transferred to the wafer exhibits some narrowing, as shown in FIG. 10(f). The narrowing is dispersed in the longitudinal direction of the pattern element, yielding a relatively small variation in line width.

Since the thickened regions of the transferred pattern element are longitudinally shifted along the upper and lower edges, as shown in FIG. 10(d), the variation in line width of the pattern element is smaller than in the first representative embodiment. A similar phenomenon is evident in the transferred pattern element shown in FIG. 10(f), but characterized by narrowing rather than thickening. The desired range for the length L₆ is similar to the desired range for the length L₁ in the first representative embodiment.

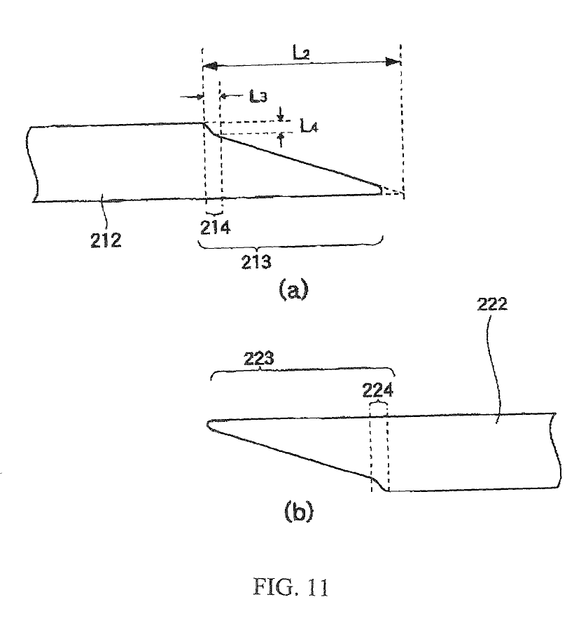

Further with respect to this embodiment, the design of pattern-element portions may be performed with appropriate consideration given to the rounding of the tips of mating ends (caused by fabrication errors originating in the performance of the mask-drawing apparatus), in the same manner as in the second representative embodiment. Modifications to the shapes of the respective mating ends are shown in FIGS. 11 (a)-1(b), respectively. I.e., if the oblique part 213 of the pattern-element portion 212 (FIG. 11(a)) and the oblique part 223 of the pattern-element portion 222 (FIG. 11(b)) have rounded tips, the first pattern-element portion is defined in its mask subregion such that the oblique part 213 has a step 214 in a location corresponding to the position of the rounded tip of the oblique part 223. Similarly, the second pattern-element portion is defined in its mask subregion such that the oblique part 223 has a step 224 in a location corresponding to the position of the rounded tip of the oblique part 213. The design-specified parameters L₂-L₄, etc., of the pattern-element portions 212, 222 can be optimized using, for example, a simulation as shown in FIG. 8.

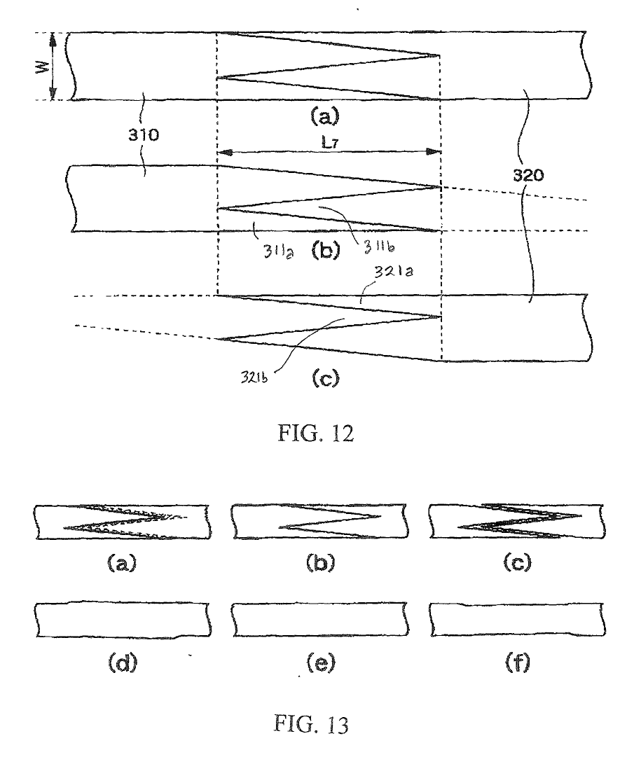

FIGS. 12(a)-12(c) depict a manner of stitching together two long linear pattern-element portions according to the fourth representative embodiment. The pattern element as designed has a long linear profile similar to that shown in FIG. 12(a). This pattern element is split into two complementary pattern-element portions 310 and 320, shown in FIGS. 12(b) and 12(c), respectively, defined on separate mask subregions of the same mask or of different masks. The mating end of the pattern-element portion 310 includes an oblique part 311a and a recession 311b. The mating end of the pattern-element portion 320 is complementary to the mating end of the pattern-element portion 310. By configuring respective mating ends in this manner, variations in line width of the pattern element that are formed when the pattern-element portions 310, 320 are stitched together on the wafer can be kept very small, similar to the first representative embodiment, even in the face of variations in the amount of overlap of the mating ends.

FIGS. 13(a)-13(f) depict various conditions of overlap and the consequences thereof, using the pattern-element portions shown in FIGS. 12(b) and 12(c). By way of example, the design-specified line width W of the pattern-element portions shown in FIG. 12(a) is 0.1 μm (100 nm), and the length L₇ of the mating ends is 400 nm.

Whenever the amount of overlap of the mating ends as projected onto the wafer is zero as shown in FIG. 13(b), the line width of the transferred pattern element is unchanged at the desired 100 nm, as shown in FIG. 13(e). Whenever the mating ends overlap due to a positioning error of the pattern-element portions as projected, as shown in FIG. 13(a), the line width of the transferred pattern element is thickened slightly. The thickening is dispersed longitudinally, yielding a very small variation in the line width of the transferred pattern element, as shown in FIG. 13(d). Whenever the mating ends exhibit “underlap” due to a positioning error, as shown in FIG. 13(c), the line width of the transferred pattern element is narrowed slightly. The narrowing is dispersed longitudinally, yielding a very small variation in the line width of the transferred pattern element, as shown in FIG. 13(f).

In FIG. 13(d), the thickened regions are shifted longitudinally relative to each other on the “upper” and “lower” edges of the transferred pattern element. Consequently, the variation in line width is smaller than the variation obtained with the first representative embodiment. Similarly, in FIG. 13(f), the narrowed portions are shifted longitudinally relative to each other on the “upper” and “lower edges of the pattern element. Thus, if the two pattern-element portions 310, 320 are shifted relative to each other in the longitudinal direction, the probability of a break in the pattern element is very low. The preferred range of the length L₇ is similar to the range for the length L₁ in the first representative embodiment.

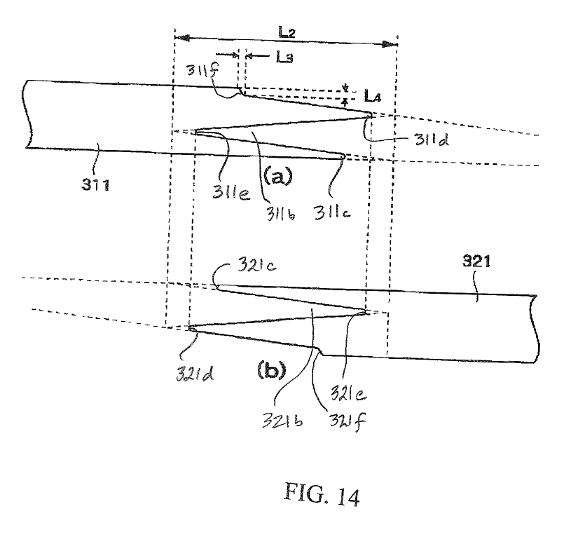

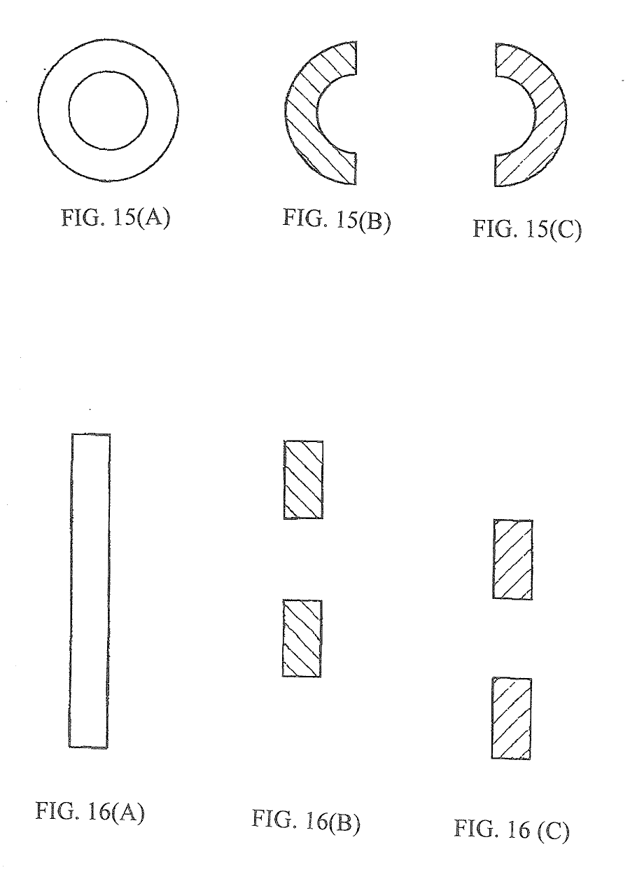

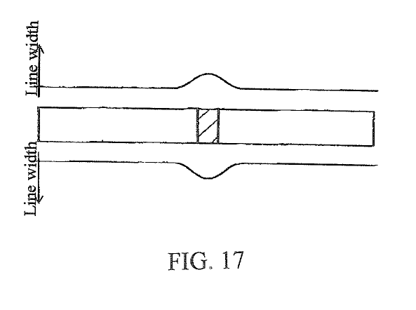

In this embodiment, similar to the second representative embodiment, pattern elements (and complementary portions thereof) can be designed with consideration given to the rounding of tips of mating ends of the pattern-element portions due to fabrication errors in the performance of the mask-drawing apparatus. An exemplary situation is shown in FIGS. 14(a)-14(b). In FIG. 14(a), the “right-hand” mating end has rounded tips 311c, 311d and a rounded “bottom” 311e of the recession 311b. In FIG. 14(b), the “left-hand” mating end has rounded tips 321c, 321d and a rounded “bottom” 321e of the recession 321b. A first mask subregion is prepared such that the pattern-element portion 311 includes a step 311f situated to correspond to the position of the curved tip 321c of the complementary mating end. Similarly, a second mask subregion is prepared such that the pattern-element portion 321 includes a step 321f situated to correspond to the position of the curved tip 311c of the complementary mating end. In FIG. 14(a), the parameters L₂-L₄ of the pattern-element portions 311, 321 can be optimized using, e.g., a simulation such as that shown in FIG. 8.

As can be ascertained from the foregoing description, according to the invention, whenever pattern elements are split on a mask into pattern-element portions, the respective mating ends of the pattern-element portions are configured with complementary oblique features. As a result, when the pattern-element portions are exposed onto the wafer, portions of the transferred pattern elements subjected to double exposure (due to positioning errors) are reduced in size compared to conventional methods. As a result, the variation in line width in connected regions of the transferred pattern is reduced compared to conventional methods, even with a variation in beam blur of the electron beam used to make the lithographic exposure.

What is claimed is:

1. In a method for manufacturing a microelectronic device, a lithographic process for transferring a pattern to a resist layer on a wafer, wherein the pattern includes pattern elements split among respective mask subregions that are exposed onto the resist using a charged-particle-beam lithographic-exposure apparatus that places and stitches together images of the mask subregions on the wafer to form the pattern on the wafer, the method comprising:
(a) in a first mask subregion, defining a first pattern-element portion having a line width and a respective mating end including a protrusion in which the line width progressively narrows toward a tip of the protrusion, the protrusion having a length that is 1 to 5 times the line width of the first pattern-element portion;
(b) in a second mask subregion, defining a second pattern-element portion having a line width and a respective mating end including a recess shaped complementarily to the protrusion so that, when the first and second pattern-element portions are exposed onto the resist, the portions collectively form a contiguous pattern element, the recess having a length that is 1 to 5 times the line width of the second pattern-element portion; and
(c) using the charged-particle-beam lithographic-exposure apparatus, transferring the first and second mask subregions onto the resist in a manner such that the respective mating ends of the first and second pattern-element portions are stitched together in the pattern on the wafer.

2. In a method for manufacturing a microelectronic device, a lithographic process for transferring a pattern to a resist layer on a wafer, wherein the pattern includes pattern elements split among respective mask subregions that are exposed onto the resist using a charged-particle-beam lithographic-exposure apparatus that places and stitches together images of the mask subregions on the wafer to form the pattern on the wafer, the method comprising:
(a) in a first mask subregion, defining a first pattern-element portion having a line width and a first mating end shaped as a recess flanked by respective protrusions, the protrusions each having a respective rounded tip and a respective width that progressively narrows toward the respective rounded tip;
(b) in a second mask subregion, defining a second pattern-element portion having a line width and a second mating end that is substantially complementary to the first mating end, the second mating end including (i) a step region disposed so as to be located, whenever respective images of the first and second pattern-element portions are stitched together, adjacent the respective rounded tips of the protrusions of the first mating end, and (ii) a protrusion extending from the step region and disposed so as to be located, whenever respective images of the first and second pattern-element portions are stitched together, in the recess of the first mating end; and
(c) using the charged-particle-beam lithographic-exposure apparatus, transferring the first and second mask subregions onto the resist in a manner such that the first and second mating ends are stitched together in the pattern on the wafer.

3. The method of claim 2, wherein:
in step (a) the recess in the first mating end is defined with a length that is 1 to 5 times the line width of the first pattern-element portion; and
in step (b) the protrusion of the second mating end is defined with a length of 1 to 5 times the line width of the second pattern-element portion.

4. In a method for manufacturing a microelectronic device, a lithographic process for transferring a pattern to a resist layer on a wafer, wherein the pattern includes pattern elements split among respective mask subregions that are exposed onto the resist using a charged-particle-beam lithographic-exposure apparatus that places and stitches together images of the mask subregions on the wafer to form the pattern on the wafer, the method comprising:
(a) in a first mask subregion, defining a first pattern-element portion having a line width and a respective mating end defining a respective protrusion extending at an oblique angle relative to a longitudinal direction of the first pattern-element portion and progressively narrowing toward a distal tip of the protrusion;
(b) in a second mask subregion, defining a second pattern-element portion having a line width and a respective mating end defining a respective protrusion extending at an oblique angle relative to a longitudinal direction of the second pattern-element portion and having a profile that is complementary to the protrusion of the mating end of the first pattern-element portion; and
(c) using the charged-particle-beam lithographic-exposure apparatus, transferring the first and second mask subregions onto the resist in a manner such that the respective mating ends of the first and second pattern-element portions are stitched together in the pattern on the wafer.

5. The method of claim 4, wherein:
in step (a) the protrusion of the mating end of the first pattern-element portion is defined such that the distal tip of the protrusion is rounded, wherein the protrusion of the first pattern-element portion includes a proximal step region situated so as to be adjacent the rounded distal tip of the protrusion of the mating end of the second pattern-element portion whenever the first and second pattern-element portions are stitched together on the wafer; and
in step (b), the protrusion of the mating end of the second pattern-element portion is defined such that the distal tip of the protrusion is rounded, wherein the protrusion of the second pattern-element portion includes a proximal step region situated so as to be adjacent the rounded distal tip of the protrusion of the mating end of the first pattern-element portion whenever the first and second pattern-element portions are stitched together on the wafer.

6. The method of claim 4, wherein:
in step (a), the protrusion of the first pattern-element portion is defined with a length of 1 to 5 times the line width of the first pattern-element portion; and
in step (b), the protrusion of the second pattern-element portion is defined with a length of 1 to 5 times the line width of the second pattern-element portion.

7. In a method for manufacturing a microelectronic device, a lithographic process for transferring a pattern to a resist layer on a wafer, wherein the pattern includes pattern elements split among respective mask subregions that are exposed onto the resist using a charged-particle-beam lithographic-exposure apparatus that places and stitches together images of the mask subregions on the wafer to form the pattern on the wafer, the method comprising:
(a) in a first mask subregion, defining a first pattern-element portion having a line width and a respective mating end including a respective protrusion having an edge extending obliquely to a length dimension of the first pattern-element portion, the protrusion including a respective recess;
(b) in a second mask subregion, defining a second pattern-element portion having a line width and a respective mating end that is complementary to the mating end of the first pattern-element portion; and
(c) using the charged-particle-beam lithographic-exposure apparatus, transferring the first and second mask subregions onto the resist in a manner such that the respective mating ends of the first and second pattern-element portions are stitched together in the pattern on the wafer.

8. The method of claim 7, wherein:
in step (a) the recess defined in the protrusion of the mating end of the first pattern-element portion divides the respective protrusion into first and second protrusion portions that flank the recess, each protrusion portion having a respective rounded distal end;
in step (b) the mating end of the second pattern-element portion is defined to include a respective protrusion having an edge extending obliquely to a length dimension of the second pattern-element portion, the protrusion including a recess that divides the respective protrusion into first and second protrusion portions that flank the recess, each protrusion portion having a respective rounded distal end;
in step (a) the obliquely extending edge includes a respective step region situated so as to be located adjacent a rounded tip of a protrusion portion of the mating end of the second pattern-element portion when the first and second pattern-element portions are stitched together on the wafer; and
in step (b) the obliquely extending edge includes a respective step region situated so as to be located adjacent a rounded tip of a protrusion portion of the mating end of the first pattern-element portion when the first and second pattern-element portions are stitched together on the wafer.

9. The method of claim 7, wherein in step (a), the recess defined in the protrusion of the mating end of the first pattern-element portion is defined to have a length of 1 to 5 times the line width of the first pattern-element portion.
